(19) United States
(12) Patent Application Publication
(10) Pub. No.: US 2010/0015816 A1
(43) Pub. Date: Jan. 21, 2010

(54) METHODS TO PROMOTE ADHESION BETWEEN BARRIER LAYER AND POROUS LOW-K FILM DEPOSITED FROM MULTIPLE LIQUID PRECURSORS

(76) Inventors: Kelvin Chan, San Jose, CA (US); Kang Sub Yim, Santa Clara, CA (US); Alexandros T. Demos, Fremont, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/173,659

(22) Filed: Jul. 15, 2008

(51) Int. Cl. H01L 21/31

(52) U.S. Cl. 438/778; 257/E21.24

(57) ABSTRACT

A method for processing a substrate is provided, wherein a first organosilicon precursor, a second organosilicon precursor, a porogen, and an oxygen source are provided to a processing chamber. The first organosilicon precursor comprises compounds having generally low carbon content. The second organosilicon precursor comprises compounds having higher carbon content. The porogen comprises hydrocarbon compounds. RF power is applied to deposit a film on the substrate, and the flow rates of the various reactant streams are adjusted to change the carbon content as portions of the film are deposited. In one embodiment, an initial portion of the deposited film has a low carbon content, and is therefore oxide-like, while successive portions have higher carbon content, becoming oxycarbide-like. Another embodiment features no oxide-like initial portion. Post-treating the film generates pores in portions of the film having higher carbon content.

### CROSS-REFERENCE TO RELATED APPLICATIONS

This application is related to co-pending U.S. patent application Ser. No. 11/046,090, filed Jan. 28, 2005, published under Publication No. 2005/0233591. This application is also related to U.S. patent application Ser. No. 11/142,124, filed Jun. 1, 2005, now issued as U.S. Pat. No. 7,259,111; and U.S. patent application Ser. No. 11/123,501, filed May 4, 2005, now issued as U.S. Pat. No. 7,189,658. Each of the aforementioned related patent applications is herein incorporated by reference.

### BACKGROUND OF THE INVENTION

1. Field of the Invention

Embodiments of the present invention generally relate to the fabrication of integrated circuits. More particularly, embodiments of the present invention relate to a process for depositing low dielectric constant films for integrated circuits.

2. Description of the Related Art

Integrated circuit geometries have dramatically decreased in size since such devices were first introduced several decades ago. Since then, integrated circuits have generally followed the two year/half-size rule (often called Moore's Law), which means that the number of devices on a chip doubles every two years. Today's fabrication facilities are routinely producing devices having 90 nm and even 65 nm feature sizes, and tomorrow's facilities soon will be producing devices having even smaller feature sizes.

The continued reduction in device geometries has generated a demand for films having lower dielectric constant (k) values because the capacitive coupling between adjacent metal lines must be reduced to further reduce the size of devices on integrated circuits. In particular, insulators having low dielectric constants, less than about 4.0, are desirable. Examples of insulators having low dielectric constants include spin-on glass, fluorine-doped silicon glass (FSG), carbon-doped oxide, and polytetrafluoroethylene (PTFE), which are all commercially available.

More recently, low dielectric constant organosilicon films having k values less than about 3.0 and even less than about 2.5 have been developed. One method that has been used to develop low dielectric constant organosilicon films has been to deposit the films from a gas mixture comprising an organosilicon compound and a compound comprising thermally labile species or volatile groups and then post-treat the deposited films to remove the thermally labile species or volatile groups, such as organic groups, from the deposited films. The removal of the thermally labile species or volatile groups from the deposited films creates nanometer-sized voids in the films, which lowers the dielectric constant of the films, as air has a dielectric constant of approximately 1.

While low dielectric constant organosilicon films that have desirable low dielectric constants have been developed as described above, some of these low dielectric constant films have exhibited less than desirable mechanical properties, such as poor mechanical strength, which renders the films susceptible to damage during subsequent semiconductor processing steps. Semiconductor processing steps which can damage the low dielectric constant films include plasma-based etching processes that are used to pattern the low dielectric constant films. Ashing processes to remove photoresists or bottom anti-reflective coatings (BARC) from the dielectric films and wet etch processes can also damage the films.

Thus, there remains a need for a process for making low dielectric constant films that have improved mechanical properties and resistance to damage from subsequent substrate processing steps.

### SUMMARY OF THE INVENTION

Embodiments of the invention provide a method of processing a substrate, comprising positioning the substrate on a support in a processing chamber; providing a first organosilicon precursor to the chamber at a first flow rate, providing a second organosilicon precursor comprising to the chamber at a second flow rate, providing a hydrocarbon mixture to the chamber at a third flow rate, providing an oxidizing agent to the chamber at a fourth flow rate, ramping the flow rate of the second organosilicon precursor to a fifth flow rate, ramping the flow rate of the oxidizing agent to a sixth flow rate, and diverting the hydrocarbon mixture to bypass the chamber for at least part of the time the substrate is being processed. In some embodiments, the flow rate of the first organosilicon precursor and the hydrocarbon mixture may be ramped as well. In some embodiments, the ratio of carbon to silicon atoms in the reaction mixture may increase from about 6:1 to about 20:1.

Other embodiments of the invention provide a method of processing a substrate, comprising providing a plurality of gas mixtures comprising silicon, carbon, oxygen, and hydrogen to a processing chamber, wherein at least two of the gas mixtures are silicon sources, providing plasma processing conditions by applying RF power to the processing chamber, reacting at least a portion of the gas mixtures to deposit a film on the substrate, and adjusting the carbon content in portions of the deposited film by adjusting a ratio of carbon to silicon atoms in the processing chamber during application of RF power.

Further embodiments of the invention provide a method of depositing a low-k dielectric film on a substrate disposed in a processing chamber, comprising providing a first gas mixture comprising one or more compounds having —Si—Cₓ—Si— or —Si—O—Cₓ—O—Si— bonds, and having a ratio of carbon to silicon atoms less than about 6:1, to the processing chamber, with the first gas mixture, providing a second gas mixture comprising one or more compounds having —Si—Cₓ—Si— or —Si—O—Cₓ—O—Si— bonds, and having a ratio of carbon to silicon atoms greater than about 8:1, to the processing chamber, providing a third gas mixture comprising one or more hydrocarbon compounds to the processing chamber, at least one of the one or more hydrocarbon compounds having thermally labile groups, to the processing chamber, providing a fourth gas mixture comprising oxygen sources to the processing chamber, applying RF power and reacting at least a portion of the gas mixtures to deposit a film on the substrate, while applying RF power, adjusting one or more of the gas mixtures containing carbon to change the deposition rate of carbon in the film, and post-treating the deposited film to lower the dielectric constant of the film.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a process flow diagram summarizing a method according to one embodiment of the invention.

FIG. 2 is a process flow diagram summarizing a method according to another embodiment of the invention.

FIGS. 3A-3D are graphs showing flow rates of various gas mixtures in different embodiments of the invention.

FIG. 4 is a graph showing carbon concentration of a film according to one embodiment of the invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

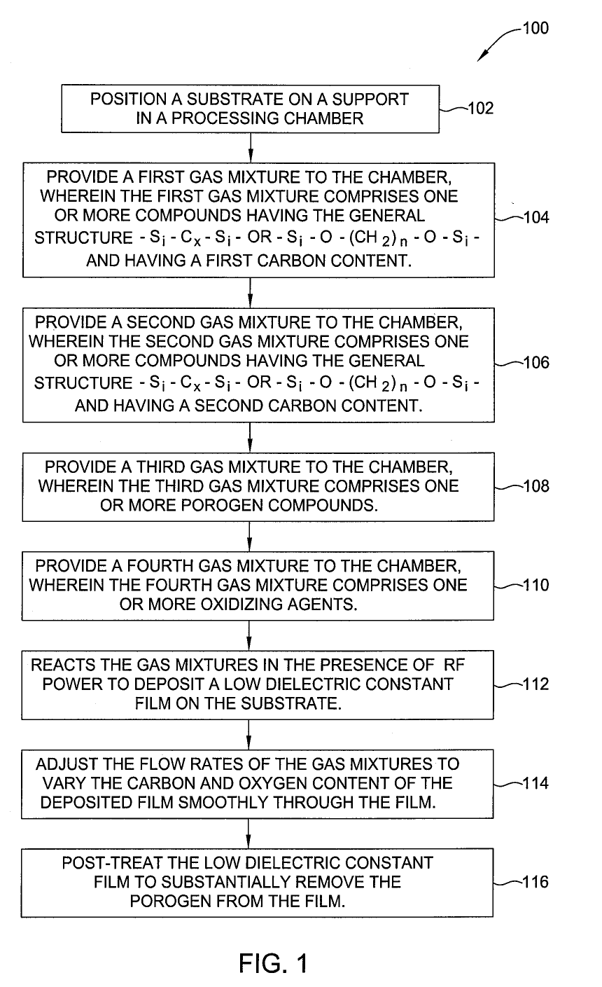

The present invention provides a method of depositing a low dielectric constant film. The low dielectric constant film comprises silicon, oxygen, and carbon. The film also comprises nanometer-sized pores. The low dielectric constant film has a dielectric constant of about 3.0 or less, preferably about 2.5 or less, such as between about 2.0 and 2.2. The low dielectric constant film may have an elastic modulus of at least about 6 GPa. The low dielectric constant film may be used as an intermetal dielectric layer, for example. A method of depositing a low dielectric constant film according to an embodiment of the invention will be described briefly with respect to FIG. 1 and then further described below.

FIG. 1 is a process flow diagram summarizing a method 100 according to one embodiment of the invention. At 102, a substrate is positioned on a substrate support in a processing chamber. At 104, a first gas mixture is provided to the chamber. The first gas mixture generally comprises one or more compounds containing silicon and carbon. In preferred embodiments, the compounds are organosilicon compounds having the general structure —Si—Cₓ—Si—, wherein x is between 1 and 4 or the general structure —Si—O—(CH₂)ₙ—O—Si—, wherein n is between 1 and 4. At 106, a second gas mixture comprising one or more compounds containing silicon and carbon is provided to the chamber. The silicon- and carbon-containing compounds of the second gas mixture may also be organosilicon compounds having the general structure described above. In most embodiments, the second gas mixture will preferably have a higher carbon content than the first gas mixture. In some embodiments, the second gas mixture will contain compounds having a higher ratio of carbon atoms to silicon atoms than the compounds of the first gas mixture. A third gas mixture, comprising one or more porogen compounds, is provided to the chamber at 108. The porogen compounds will generally be hydrocarbons, at least one of which has one or more thermally labile groups. The thermally labile groups will generally be cyclic groups, such as unsaturated cyclic organic groups. A fourth gas mixture, comprising one or more oxidizing agents is provided to the chamber at 110.

At 112, the gas mixtures are reacted in the presence of RF power to deposit a low dielectric constant film on a substrate in the chamber. The porogens of the third gas mixture may be reacted with the silicon- and carbon-containing compounds of the first and second gas mixture. The gases react to deposit a film that retains the thermally labile groups therein. Post-treating the film, as indicated at 116, results in the decomposition and evolution of the porogens and/or the thermally labile groups from the film, resulting in the formation of voids or nanometer-sized pores in the film.

The carbon and oxygen content of the film is adjusted at 114 by adjusting the flow rates of the gas mixtures. In one embodiment, the flow rate of the first gas mixture is constant, and the flow rate of the second gas mixture is ramped-up. This increases the amount of carbon available for deposition in the film, resulting in a carbon content that increases smoothly as the film grows. In another embodiment, the flow rate of the third gas mixture is ramped up to add carbon to the reaction. In another embodiment, the flow rate of the fourth gas mixture is ramped down. Adjusting the carbon and oxygen content of portions of the film improves adhesion of the film at interfaces by providing an oxide-like composition to interface with an oxide film, while smoothly increasing the carbon content of the film with distance from the oxide interface.

The film is post-treated at 116 to substantially remove the porogen from the low dielectric constant film.

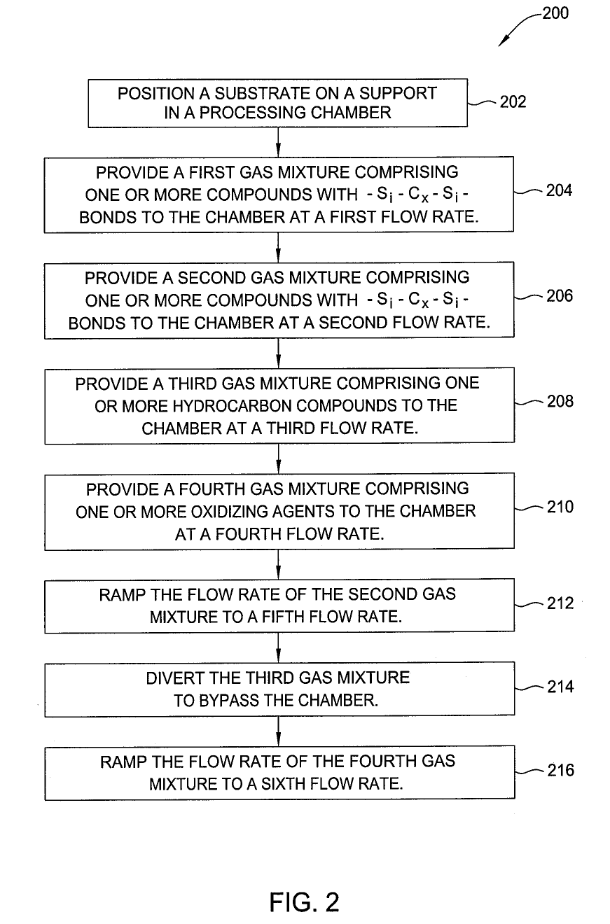

FIG. 2 is a process flow diagram summarizing a method 200 according to another embodiment of the invention. A substrate is positioned on a substrate support in a processing chamber at 202. At 204, a first gas mixture comprising one or more compounds having —Si—Cₓ—Si— bonds is provided to the chamber at a first flow rate. At 206, a second gas mixture comprising one or more compounds having —Si—Cₓ—Si— bonds is provided to the chamber at a second flow rate. The second gas mixture will generally have a different composition than the first gas mixture. In some embodiments, the second gas mixture will have a higher proportion of carbon atoms to silicon atoms than the first gas mixture. At 208, a third gas mixture comprising one or more hydrocarbon compounds is provided to the chamber at a third flow rate. At least one of the hydrocarbon compounds in the third gas mixture will have one or more thermally labile groups, as described herein elsewhere. At 210, a fourth gas mixture comprising one or more oxidizing agents is provided to the chamber at a fourth flow rate.

At 212, the flow rate of the second gas mixture is ramped to a fifth flow rate, which may be higher than the second flow rate. Increasing the flow rate of the second gas mixture generally increases the deposition of carbon in the film. The fifth flow rate may be higher or lower than the first flow rate.

At 214, the third gas mixture is diverted to bypass the chamber. Diverting the third gas mixture reduces the carbon content of the reaction mixture, resulting in a lower deposition rate of carbon in the film and therefore a lower carbon content in the portions of the film deposited from the reduced-carbon reaction mixture. This can be useful in forming an oxide-like portion of the film to interface strongly with an oxide dielectric. After an oxide-like portion of the film is formed, the diverted third gas mixture may be restored to the chamber to add carbon to the reaction mixture. The added carbon results in higher deposition rate of carbon in the film, resulting in higher carbon content of those portions of the film. In this way, the carbon content of the deposited film may be smoothly adjusted from an oxide-like portion to an oxycarbide-like portion.

At 216, the flow rate of the fourth gas mixture is ramped to a sixth flow rate, which may be lower than the fourth flow rate. Decreasing the flow rate of the fourth gas mixture generally decreases the deposition of oxygen in the film, resulting in relatively higher deposition rate of carbon, and higher carbon content of the portions of the film deposited from the low-oxygen reaction mixture.

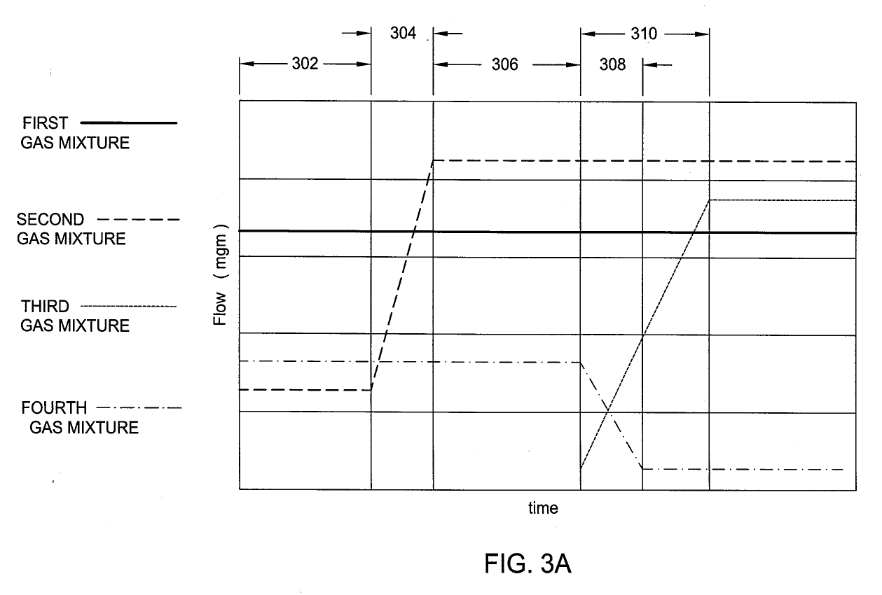

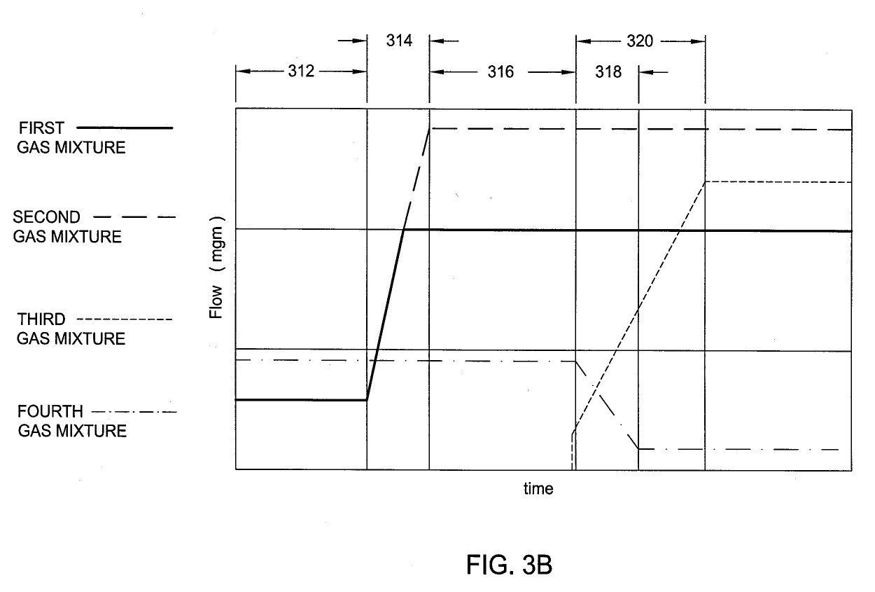

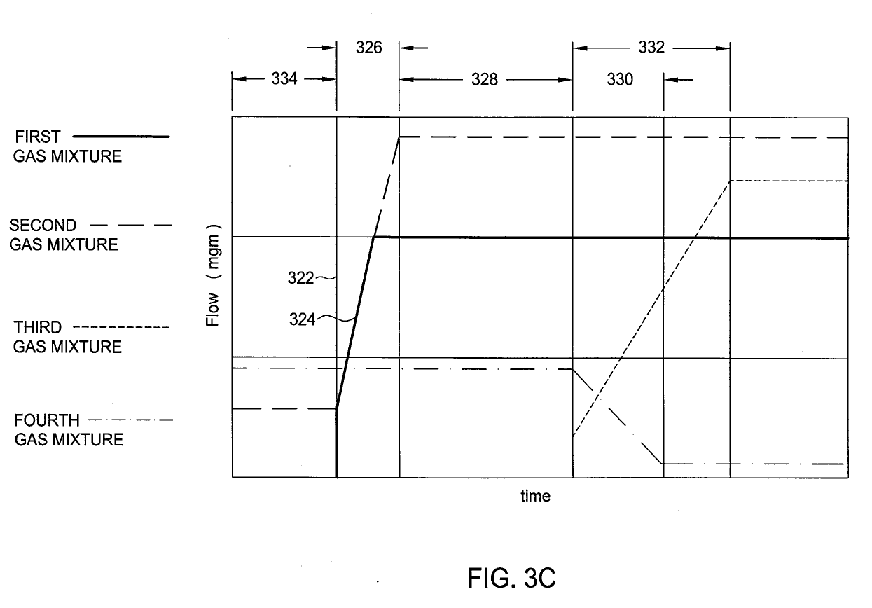

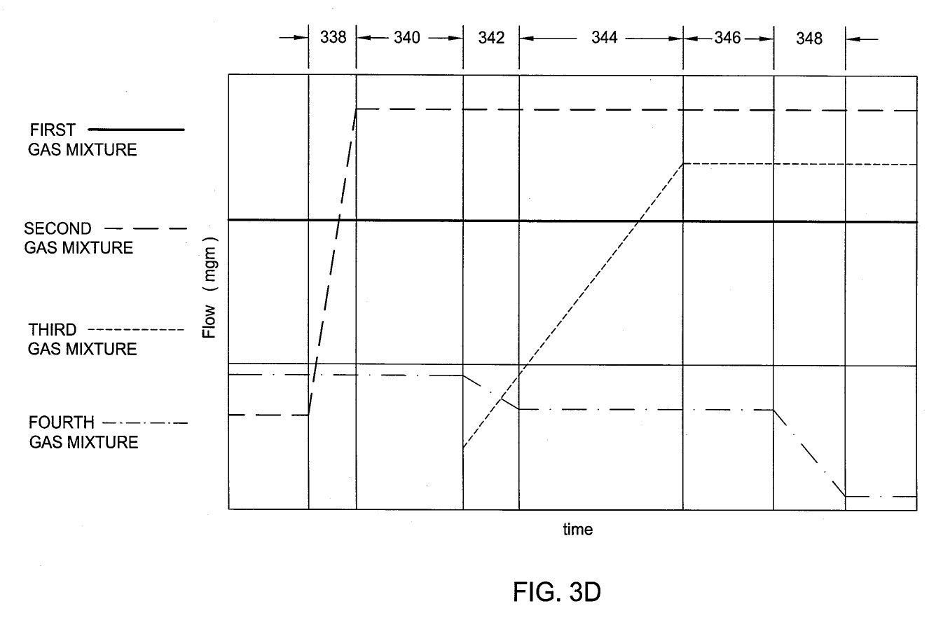

FIGS. 3A-3D are graphs showing flow rates of the various gas mixtures described above in different exemplary embodiments. In the embodiment described by the graph of FIG. 3A, the flow rate of the first gas mixture is held constant throughout the process. Initially, only the first, second, and fourth gas mixtures flow into the chamber. The third gas mixture does not initially flow into the chamber, but may be diverted to bypass the chamber. RF power is applied to the initial gas mixture to deposit an initiation film during the period represented by initiation period 302. During a first transition period 304, the flow rate of the second gas mixture is ramped up while the RF power continues. During the first transition period 304 the concentration of elements in the reaction mixture changes, changing the composition of the deposited film. The film deposited during the first deposition period 306 thus has a different composition from that deposited during the initiation period 302. Because RF power was continually applied to the reaction mixture, however, the film composition changes smoothly, resulting in no interface within the film. Adhesion strength of the film is increased by avoiding such interfaces. During a second transition period 310, the third gas mixture, heretofore bypassing the chamber, is restored to flow into the chamber, and the flow rate of the third gas mixture is ramped up, adding carbon to the reaction mixture and the deposited film. During this same period, the flow rate of the fourth gas mixture is ramped down to maintain reactor pressure and increase the ratio of carbon atoms to silicon atoms in the reaction mixture, further increasing deposition rate of carbon in the film. Reactor pressure may also be maintained by adjusting carrier gases flowing with the various precursors. After the second transition period 310, precursors reach their final flow rates for a final deposition period. The fourth gas mixture may ramp during a third transition period 308 that may be longer or shorter than the second transition period 310 of the third gas mixture, due to different starting and ending flow rates.

For the embodiment illustrated by FIG. 3A, the following reaction conditions and flow rates are generally beneficial:

| | | First | Final |
|---|---|---|---|
| | Initiation | Deposition | Deposition |
| First Gas Mixture (mgm) | 800-1200 | 800-1200 | 800-1200 |
| Second Gas Mixture (mgm) | 200-400 | 1100-1700 | 1100-1700 |
| Third Gas Mixture (mgm) | 100-300 | 100-300 | 1000-1500 |
| | (diverted) | (diverted) | |
| Fourth Gas Mixture (mgm) | 300-600 | 300-600 | 10-100 |

Ramp rates for the various transitions are generally between 500 mgm/sec and 1000 mgm/sec for the first and second gas mixtures, as applicable, and between 100 mgm/sec and 500 mgm/sec for the third and fourth gas mixtures, as applicable. For diverted streams, it is generally preferable to restore the stream flowing to the chamber before ramping the flow rate up, to avoid a pressure shock to the reactor. Alternately, the ramp-up in flow rate of the diverted stream may begin at the same time the stream is restored to the reactor, or just before.

The time intervals of the first deposition period 306 and the final deposition period will depend on the desired thickness of the two portions of the film deposited under the different conditions. Depositing a film with higher levels of carbon, and ultimately higher porosity, will result in lower overall dielectric constant for the film. The first deposition period 306 should be long enough to ensure cohesion of the entire film.

FIG. 3B is a graph of flow rates according to another embodiment. An initiation period 312 is followed by a first transition period 314, a first deposition period 316, a second transition period 320, and a final deposition period, as before. In the embodiment of FIG. 3B, the flow rate of the first gas mixture is ramped during the first transition period 314, along with the flow rate of the second gas mixture. In this embodiment, the first and second gas mixtures are ramped simultaneously during the first transition period 314. The second transition period in this embodiment is similar in overall plan to that of the embodiment of FIG. 3A, with the third gas mixture ramping over the entire transition period 320 and the fourth gas mixture ramping over a shorter transition period 318.

For the embodiment illustrated by FIG. 3B, the following reaction conditions and flow rates are generally beneficial:

| | | First | Final |
|---|---|---|---|
| | Initiation | Deposition | Deposition |
| First Gas Mixture (mgm) | 100-500 | 800-1200 | 800-1200 |
| Second Gas Mixture (mgm) | 100-500 | 1100-1700 | 1100-1700 |
| Third Gas Mixture (mgm) | 100-300 | 100-300 | 1000-1500 |
| | (diverted) | (diverted) | |
| Fourth Gas Mixture (mgm) | 300-600 | 300-600 | 10-100 |

Ramp rates may be similar to those provided above, but different ramp rates may be used, depending on the concentration profiles desired for the deposited film.

FIG. 3C shows another embodiment. In this embodiment, the first gas mixture is diverted during the initiation period 334, such that only the second and fourth gas mixtures flow into the reactor. The first gas mixture may be restored to the reactor at a first flow rate and then ramped to a second flow rate during the first transition period 326, as shown by line 324, or it may be restored to the reactor at the second flow rate without ramping, as shown by line 322. The flow rate of the second gas mixture is also ramped during this period. As before, the first deposition period 328 is followed by a second transition period 332, during which the third and fourth gas mixtures are ramped to final flow rates, the fourth gas mixture ramping over a third transition period 330 that may be longer or shorter than the second transition period 332.

For the embodiment illustrated by FIG. 3C, the following reaction conditions and flow rates are generally beneficial:

| | | First | Final |
|---|---|---|---|
| | initiation | Deposition | Deposition |
| First Gas Mixture (mgm) | 200-1200 | 800-1200 | 800-1200 |
| | (diverted) | | |
| Second Gas Mixture (mgm) | 100-500 | 1100-1700 | 1100-1700 |
| Third Gas Mixture (mgm) | 100-300 | 100-300 | 1000-1500 |
| | (diverted) | (diverted) | |
| Fourth Gas Mixture (mgm) | 300-600 | 300-600 | 10-100 |

Ramp rates may be similar to those provided above, but different ramp rates may be used, depending on the concentration profiles desired for the deposited film.

In a final exemplary embodiment illustrated by FIG. 3D, the flow rate of the first gas mixture is held constant, while the flow rate of the fourth gas mixture is ramped twice during two different transition periods. After an initiation period 326, the flow rate of the second gas mixture is ramped during a first transition period 338. After a first deposition period 340, the flow rate of the fourth gas mixture is ramped during a second transition period 342. As shown in FIG. 3D, the flow rate of the third gas mixture is ramped over the second transition period 342 and a third transition period 344. After a second deposition period 346, the flow rate of the fourth gas mixture is ramped once again in a fourth transition period 348, after which a final deposition period ensues.

For the embodiment illustrated by FIG. 3D, the following reaction conditions and flow rates are generally beneficial:

| | | First | Second | Final |
|---|---|---|---|---|
| | Initiation | Deposition | Deposition | Deposition |
| First Gas Mixture | 800-1200 | 800-1200 | 800-1200 | 800-1200 |
| (mgm) | | | | |
| Second Gas Mixture | 100-500 | 1100-1700 | 1100-1700 | 1100-1700 |
| (mgm) | | | | |
| Third Gas Mixture | 100-300 | 100-300 | 1000-1500 | 1000-1500 |
| (mgm) | (diverted) | (diverted) | | |
| Fourth Gas Mixture | 300-600 | 300-600 | 200-400 | 10-100 |
| (mgm) | | | | |

Ramp rates may be similar to those provided above, but different ramp rates may be used, depending on the concentration profiles desired for the deposited film.

The times for the various periods described above may be selected depending on the needs of particular embodiments. In some embodiments, the initiation period may last from 0 to 10 seconds. An initiation period of 0 seconds means that changing flow rates of gas streams begins immediately upon introducing them to the chamber. Thus, embodiments with no initiation period are contemplated. In some such embodiments, the process begins with a first transition period and a first deposition period, possibly followed by other transition and deposition periods, with generally increasing carbon content in the reaction mixture and the deposited film during the successive transition and deposition periods. In other embodiments, the first transition period may last from 1 to 10 seconds. In some embodiments, each deposition period may last from 1 to 180 seconds. In some embodiments, the second transition period may last from 1 to 180 seconds. In still other embodiments, the third and fourth transition periods, if required, may last from 1 to 60 seconds.

The initiation period preferably results in deposition of a thin portion of the film. In most embodiments, this portion will have thickness less than about 10 Angstroms. Deposition of the thin initiation portion of the film is achieved through low deposition rate and relatively short duration. The initial deposition rate is preferably from about 500 Angstroms/minute to about 1,000 Angstroms/minute, such as about 600 Angstroms/minute, rising as the flow rate of reactant gases increases to about 3,000 Angstroms/minute during later deposition periods.

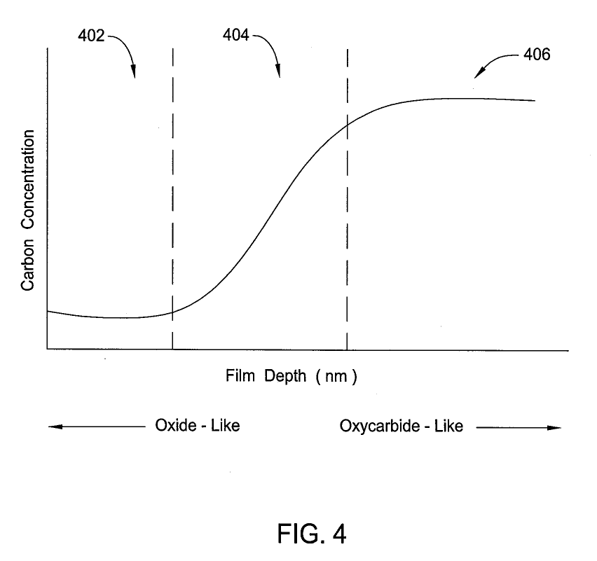

The foregoing embodiments are provided to show exemplary processing conditions operative for producing a porous low-k dielectric film with good adhesion properties. The adhesion properties of the films deposited using embodiments of the present invention generally have a carbon concentration, before post-treatment, that varies smoothly through the film. FIG. 4 is a graph showing the carbon concentration of an exemplary film. Portion 402 of the film is an oxide-like portion having a relatively low carbon concentration. Although in some embodiments the carbon concentration of the oxide-like portion may be approximately zero, a low non-zero concentration may allow for better process control through deposition of the entire film. The carbon concentration rises during the transition portion 404 of the film, generally deposited during transition and intermediate deposition periods as described above, and then reaches a maximum during the final portion 406. The final portion 406 will generally be deposited with maximum carbon, and will generally have maximum porosity after post-treating to provide low dielectric constant for the film.

Preferred compounds to be included in the first and second gas mixtures are from the class of compounds having the general formula (R¹)₃SiR²Si(R¹)₃, where each R¹ is an alkyl, alkoxy, or alkenyl group, and may be independently selected from the group consisting of CH₃, OCH₃, OC₂H₅, C═CH₂, H, and OH, and R² is selected from the group consisting of (CH₂)ₐ, C≡C, C═C, C₆H₄, C═O, (CF₂)_{b}, and combinations thereof, with a and b being 1 to 4. Other preferred compounds replace the —SiR²Si— structure with a cyclic structure wherein each silicon occupies a position in a carbon ring, which may also include oxygen atoms. Exemplary categories of compounds with these general structures include bis-sylylalkanes, disilacycloalkanes, disilaoxacycloalkanes, and disilafurans. Some exemplary compounds include bis(triethoxysilyl)methane (C₁₃H₃₂O₆Si₂), tetramethyl-1,3-disilacyclobutane (C₆H₁₆Si₂), tetramethyl-2,5-disila-1-oxacyclopentane, and tetramethyldisilafuran (C₆H₁₆OSi₂). Other exemplary categories of compounds have the general formula (R⁶)₃SiO(CH₂)_{f}OSi(R⁶)₃, wherein each R⁶ is independently selected from the group consisting of CH₃, OCH₃, OC₂H₅, C═CH₂, H, and OH, and f is 1 to 4. This category of compounds includes, for example, bis-alkylsiloxyalkanes. An example of such a compound is bis(trimethylsiloxy)ethane (C₈H₂₂O₂Si₂).

The one or more compounds containing silicon and carbon may also comprise organosilicon compounds that do not include the general structures described above. For example, the one or more compounds may include methyldiethoxysilane (MDEOS), tetramethylcyclotetrasiloxane (TMCTS), octamethylcyclotetrasiloxane (OMCTS), trimethylsilane (TMS), pentamethylcyclopentasiloxane, hexamethylcyclotrisiloxane, dimethyldisiloxane, tetramethyldisiloxane, hexamethyldisiloxane (HMDS), 1,3-bis(silanomethylene)disiloxane, bis(1-methyldisiloxanyl)methane, bis(1-methyldisiloxanyl)propane, hexaethoxydisiloxane (HMDOS), dimethyldimethoxysilane (DMDMOS), or dimethoxymethylvinylsilane (DMMVS).

The third gas mixture generally comprises one or more porogen compounds. The porogens are compounds that comprise thermally labile groups. The thermally labile groups may be cyclic groups, such as unsaturated cyclic organic groups. The term “cyclic group” as used herein is intended to refer to a ring structure. The ring structure may contain as few as three atoms. The atoms may include carbon, nitrogen, oxygen, fluorine, and combinations thereof, for example. The cyclic group may include one or more single bonds, double bonds, triple bonds, and any combination thereof. For example, a cyclic group may include one or more aromatics, aryls, phenyls, cyclohexanes, cyclohexadienes, cycloheptadienes, and combinations thereof. The cyclic group may also be bi-cyclic or tri-cyclic. In one embodiment, the cyclic group is bonded to a linear or branched functional group. The linear or branched functional group preferably contains an alkyl or vinyl alkyl group and has between one and twenty carbon atoms. The linear or branched functional group may also include oxygen atoms, such as in a ketone, ether, and ester. The porogen may comprise a cyclic hydrocarbon compound. Some exemplary porogens that may be used include norbornadiene (BCHD, bicycle (2.2.1)hepta-2,5-diene), alpha-terpinene (ATP), vinylcyclohexane (VCH), phenylacetate, butadiene, isoprene, cyclohexadiene, 1-methyl-4-(1-methylethyl)-benzene (cymene), 3-carene, fenchone, limonene, cyclopentene oxide, vinyl-1,4-dioxinyl ether, vinyl furyl ether, vinyl-1,4-dioxin, vinyl furan, methyl furoate, furyl formate, furyl acetate, furaldehyde, difuryl ketone, difuryl ether, difurfuryl ether, furan, and 1,4-dioxin.

The chamber into which the various gas mixtures are introduced may be a plasma enhanced chemical vapor deposition (PECVD) chamber. The plasma for the deposition process may be generated using constant radio frequency (RF) power, pulsed RF power, high frequency RF power, dual frequency RF power, or combinations thereof. An example of a PECVD chamber that may used is a PRODUCER® chamber, available from Applied Materials, Inc. of Santa Clara, Calif. However, other chambers may be used to deposit the low dielectric constant film. The chamber generally comprises a gas distribution assembly comprising a gas distribution plate, such as a showerhead. The RF power is applied to an electrode, such as the showerhead to provide plasma processing conditions. A substrate is generally disposed on a substrate support, which together with the gas distribution plate cooperatively defines a reaction zone. A throttle valve is provided on the exhaust line to maintain chamber pressure. The throttle valve is adjusted during the many flow rate changes to control chamber pressure.

During the processes described above, the substrate is typically maintained at a temperature between about 100° C. and about 400° C. The chamber pressure may be between about 1 Torr and about 20 Torr, and the spacing between a substrate support and the chamber showerhead may be between about 200 mils and about 1500 mils. A power density ranging between about 0.14 W/cm² and about 2.8 W/cm², which is a RF power level of between about 100 W and about 2000 W for a 300 mm substrate, may be used. The RF power is provided at a frequency between about 0.01 MHz and 300 MHz, such as about 13.56 MHz. The RF power may be provided at a mixed frequency, such as at a high frequency of about 13.56 MHz and a low frequency of about 350 kHz. The RF power may be cycled or pulsed to reduce heating of the substrate and promote greater porosity in the deposited film. The RF power may also be continuous or discontinuous.

Exemplary UV post-treatment conditions that may be used include a chamber pressure of between about 1 Torr and about 10 Torr and a substrate support temperature of between about 350° C. and about 500° C. The UV radiation may be provided by any UV source, such as mercury microwave arc lamps, pulsed xenon flash lamps, or high-efficiency UV light emitting diode arrays. The UV radiation may have a wavelength of between about 170 nm and about 400 nm, for example. Further details of UV chambers and treatment conditions that may be used are described in commonly assigned U.S. patent application Ser. No. 11/124,908, filed on May 9, 2005, which is incorporated by reference herein. The NanoCure™ chamber from Applied Materials, Inc. is an example of a commercially available chamber that may be used for UV post-treatments.

Exemplary electron beam conditions that may be used include a chamber temperature of between about 200° C. and about 600° C., e.g. about 350° C. to about 400° C. The electron beam energy may be from about 0.5 keV to about 30 keV. The exposure dose may be between about 1 μC/cm² and about 400 μC/cm². The chamber pressure may be between about 1 mTorr and about 100 mTorr. The gas ambient in the chamber may be any of the following gases: nitrogen, oxygen, hydrogen, argon, a blend of hydrogen and nitrogen, ammonia, xenon, or any combination of these gases. The electron beam current may be between about 0.15 mA and about 50 mA. The electron beam treatment may be performed for between about 1 minute and about 15 minutes. Although any electron beam device may be used, an exemplary electron beam chamber that may be used is an EBk™ electron beam chamber available from Applied Materials, Inc. of Santa Clara, Calif.

An exemplary thermal annealing post-treatment includes annealing the film at a substrate temperature between about 200° C. and about 500° C. for about 2 seconds to about 3 hours, preferably about 0.5 to about 2 hours, in a chamber. A non-reactive gas such as helium, hydrogen, nitrogen, or a mixture thereof may be introduced into the chamber at a rate of about 100 to about 10,000 sccm. The chamber pressure is maintained between about 1 mTorr and about 10 Torr. The preferred substrate spacing is between about 300 mils and about 800 mils.

It is recognized that the organosilicon compounds provided herein can be used in gas mixtures that do not contain a porogen to chemically vapor deposit low dielectric constant films. However, while films deposited from gas mixtures that comprise the organosilicon compounds described herein and lack a porogen are expected to have improved mechanical properties compared to films deposited from porogen-free mixtures comprising other organosilicon compounds, typically, a porogen is included to provide the desired, lower dielectric constants of about 2.4 or less.

While the foregoing is directed to embodiments of the invention, other and further embodiments of the invention may be devised without departing from the basic scope thereof, and the scope thereof is determined by the claims that follow.

What is claimed is:

1. A method of processing a substrate, comprising:
positioning the substrate on a support in a processing chamber;
providing a first organosilicon precursor to the chamber at a first flow rate;
providing a second organosilicon precursor comprising to the chamber at a second flow rate;
providing a hydrocarbon mixture to the chamber at a third flow rate;
providing an oxidizing agent to the chamber at a fourth flow rate;
ramping the second flow rate of the second organosilicon precursor to a higher flow rate;
ramping the flow rate of the oxidizing agent to a higher flow rate; and
diverting the hydrocarbon mixture to bypass the chamber for at least part of the time the substrate is being processed.

2. The method of claim 1, wherein the first organosilicon precursor has a lower ratio of carbon atoms to silicon atoms than the second organosilicon precursor.

3. The method of claim 1 wherein the hydrocarbon mixture comprises one or more compounds having cyclic groups.

4. The method of claim 1, wherein ramping the second flow rate of the second organosilicon precursor comprises a ramp rate faster than the ramp rate used to ramp the oxidizing agent.

5. The method of claim 1, further comprising ramping the first flow rate of the first organosilicon precursor to a higher flow rate.

6. The method of claim 1 further comprising ramping the third flow rate of the hydrocarbon mixture to a higher flow rate.

7. The method of claim 1, wherein the first organosilicon precursor, the second organosilicon precursor, the hydrocarbon mixture, and the oxidizing agent form a reaction mixture in the process chamber, and the ratio of carbon atoms to silicon atoms in the reaction mixture increases from about 3:1 to about 20:1 during processing of the substrate.

8. A method of processing a substrate, comprising:
providing a plurality of gas mixtures comprising silicon, carbon, oxygen, and hydrogen to a processing chamber, wherein at least two of the gas mixtures are silicon sources;
providing plasma processing conditions by applying RF power to the processing chamber;
reacting at least a portion of the gas mixtures to deposit a film on the substrate; and
adjusting the carbon content in portions of the deposited film by adjusting a ratio of carbon to silicon atoms in the processing chamber during application of RF power.

9. The method of claim 8, wherein adjusting the ratio of carbon to silicon atoms in the processing chamber comprises diverting one or more of the gas mixtures to bypass the chamber.

10. The method of claim 8, wherein the plurality of gas mixtures comprises a first gas mixture comprising one or more organosilicon compounds having —Si—Cₓ—Si— bonds.

11. The method of claim 10, wherein the plurality of gas mixtures further comprises a second gas mixture comprising one or more hydrocarbon compounds having thermally labile groups.

12. The method of claim 8, further comprising generating pores in the deposited film by post-treating the substrate.

13. The method of claim 11, wherein adjusting the ratio of carbon to silicon atoms in the processing chamber comprises diverting the one or more hydrocarbon compounds to bypass the processing chamber.

14. The method of claim 8, wherein adjusting the carbon content of the deposited film comprises depositing an oxide-like portion of the film with low carbon content, increasing the carbon content smoothly in a transition portion of the film, and depositing an oxycarbide-like portion of the film with maximum carbon content.

15. A method of depositing a low-k dielectric film on a substrate disposed in a processing chamber, comprising:
providing a first gas mixture comprising one or more compounds having —Si—Cₓ—Si— or —Si—Cₓ—O—Si— bonds, and having a ratio of carbon to silicon atoms less than about 6:1, to the processing chamber;
with the first gas mixture, providing a second gas mixture comprising one or more compounds having —Si—Cₓ—Si— or —Si—O—Cₓ—O—Si— bonds, and having a ratio of carbon to silicon atoms greater than about 8:1, to the processing chamber;
providing a third gas mixture comprising one or more hydrocarbon compounds to the processing chamber, at least one of the one or more hydrocarbon compounds having thermally labile groups, to the processing chamber;
providing a fourth gas mixture comprising oxygen sources to the processing chamber;
applying RF power and reacting at least a portion of the gas mixtures to deposit a film on the substrate;
while applying RF power, adjusting the amounts of one or more of the gas mixtures containing carbon to change the deposition rate of carbon in the film; and
post-treating the deposited film to lower the dielectric constant of the film.

16. The method of claim 15, wherein the one or more compounds having —Si—Cₓ—Si— or —Si—O—Cₓ—O—Si— bonds are each selected from the group consisting of bis(triethoxysilyl)methane (C₁₃H₃₂O₆Si₂), tetramethyl-1,3-disilacyclobutane (C₆H₁₆Si₂), tetramethyl-2,5-disila-1-oxacyclopentane, tetramethyldisilafuran (C₆H₁₆OSi₂), and bis(trimethylsiloxy)ethane (C₈H₂₂O₂Si₂).

17. The method of claim 15, wherein adjusting the gas mixtures containing carbon comprises ramping the flow rate of the second gas mixture upward.

18. The method of claim 17, wherein adjusting the gas mixtures containing carbon further comprises ramping the flow rate of the third gas mixture upward.

19. The method of claim 15, wherein adjusting the gas mixtures begins when the reaction begins.

20. The method of claim 15, wherein post-treating the deposited film generates pores in the portions of the film having higher carbon content.
